(19) United States
(12) Patent Application Publication
(10) Pub. No.: US 2010/0261355 A1
(43) Pub. Date: Oct. 14, 2010

(54) METHOD FOR FORMING A HIGH QUALITY INSULATION LAYER ON A SEMICONDUCTOR DEVICE

(76) Inventors: Sang Tae AHN, Seoul (KR); Ja Chun KU, Gyeonggi-do (KR); Seung Joon JEON, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/493,279

(22) Filed: Jun. 29, 2009

(30) Foreign Application Priority Data
Apr. 10, 2009 (KR) 10-2009-0031411

(51) Int. Cl. H01L 21/314

(52) U.S. Cl. 438/787; 257/E21.269

(57) ABSTRACT

A method for forming a high quality insulation layer on a semiconductor device is presented. The method includes a first step of supplying any one of a silicon source gas and an oxygen source gas into a process chamber in which a semiconductor substrate is placed; a second step of simultaneously supplying the silicon source gas and the oxygen source gas into the process chamber having undergone the first step and depositing a silicon oxide layer on the semiconductor substrate; and a third step of supplying any one of the silicon source gas and the oxygen source gas into the process chamber having undergone the second step.

### CROSS-REFERENCE TO RELATED APPLICATIONS

The present application claims priority to Korean patent application number 10-2009-0031411 filed on Apr. 10, 2009, which is incorporated herein by reference in its entirety.

### BACKGROUND OF THE INVENTION

The present invention relates generally to manufacturing semiconductor devices, and more particularly, to a method for forming an insulation layer of a semiconductor device which can improve the quality of layers.

In the manufacture of a semiconductor device, it is essential to form an insulation layer for electrically isolating elements and for filling in spaces between conductive patterns. As a generally accepted method for forming these insulation layers, an HDP (high density plasma) process exhibits excellent step coverage has been generally used. As the integration of a semiconductor device has accelerated to more and more compact systems, the design rule of a semiconductor device also decreases. In order to electrically isolate elements and to easily fill spaces between conductive patterns, a method for forming insulation layers, which has excellent gap-fill characteristics, is needed.

In particular, when forming insulation layers by using the existing HDP process, problems arise such as problems associated with filling in spaces because of these reduced sizes demanded by the design rule for highly integrated devices. Under these circumstances, as a method for forming insulation layers in the manufacture of highly integrated semiconductor devices, a SOD (spin-on dielectric) method has been proposed. The insulation layers which are formed by using the SOD method comprise flowable insulation layers that have excellent flowability.

Briefly, first the SOD procedure involves coating on a semiconductor substrate a spin-on type flowable substance. Then, an annealing process including a baking and curing processes is conducted on the resultant semiconductor substrate coated with the flowable substance so as to bake and cure the flowable substance. However, even though the SOD layer exhibits excellent gap-fill characteristics for filling spaces between fine patterns, the SOD layer are prone to a number of disadvantages such as those associated with a high impurity content. Therefore the quality of the resultant SOD is prone to degrading.

### BRIEF SUMMARY OF THE INVENTION

Embodiments of the present invention are directed to a method for forming an insulation layer of a semiconductor device which can improve gap-fill characteristics.

Also, embodiments of the present invention are directed to a method for forming an insulation layer of a semiconductor device which can improve the quality of layers.

In one embodiment of the present invention, a method for forming an insulation layer of a semiconductor device comprises a first step of supplying any one of a silicon source gas and an oxygen source gas into a process chamber in which a semiconductor substrate is placed; a second step of simultaneously supplying the silicon source gas and the oxygen source gas into the process chamber having undergone the first step and depositing a silicon oxide layer on the semiconductor substrate; and a third step of supplying any one of the silicon source gas and the oxygen source gas into the process chamber having undergone the second step.

The silicon source gas and the oxygen source gas are supplied at a temperature of about 60˜200° C.

The silicon source gas comprises at least one of a SiH₄ gas, a Si₂H₆ gas, a Si₃H₈ gas and a Si₄H₈ gas.

The oxygen source gas comprises at least one of an O₂ gas, an O₃ gas, an H₂O gas and an H₂O₂ gas.

The oxygen source gas comprises a mixed gaseous mixture of H₂O H₂O₂.

The weight ratio of H₂O₂ gas relative to the H₂O gas in the oxygen source gas is between about 50˜140 wt %.

The first through third steps are implemented when the semiconductor substrate is maintained at a temperature of about 10˜200° C.

The second step is implemented for about 0.5˜20 seconds. After the first through third steps are implemented, the method may further comprises a fourth step of interrupting supply of a source gas supplied in the third step and conducting a purge process.

The first through fourth steps are repeatedly implemented between about 5 through 150 times.

The first step or the third step is implemented along with a purge process.

The first through third steps are repeatedly implemented between about 5 through 150 times.

The purge process is conducted by supplying at least one of an O₂ gas, an O₃ gas, an H₂ gas, an N₂ gas, an Ar gas and an He gas for about 0.5˜30 seconds.

The purge process is conducted by using a plasma process with power of about 50˜7,000 W for about 0.5˜30 seconds using at least one of an O₂ gas, an H₂ gas, an N₂ gas, an Ar gas, an He gas and an N₂O gas.

In another embodiment of the present invention, a method for forming an insulation layer of a semiconductor device comprises a first step of selectively supplying a first source gas into a process chamber in which a semiconductor substrate is placed; a second step of continuously supplying the first source gas supplied in the first step, supplying a second source gas and depositing a silicon oxide layer on the semiconductor substrate; a third step of continuously supplying the second source gas supplied in the second step and interrupting supply of the first source gas; and a fourth step of interrupting supply of the second source gas and conducting a purge process.

The first source gas comprises a silicon source gas and the second source gas comprises an oxygen source gas, or the first source gas comprises an oxygen source gas and the second source gas comprises a silicon source gas.

The silicon source gas comprises at least one of an SiH₄ gas, an Si₂H₆ gas, an Si₃H₈ gas and an Si₄H₈ gas.

The oxygen source gas comprises at least one of an O₂ gas, an O₃ gas, an H₂O gas and an H₂O₂ gas.

The first source gas and the second source gas are supplied at a temperature of about 60˜200° C.

The first source gas supplied in the first step is continuously supplied through the second step for about 1˜30 seconds in total.

The second source gas supplied in the second step is continuously supplied through the third step for about 1˜30 seconds in total.

The first through fourth steps are implemented in a state in which the semiconductor substrate is maintained at a temperature of about 10˜200° C.

The second step is implemented for about 0.5˜20 seconds.

The first step is implemented along with a purge process.

The purge process is conducted by supplying at least one of an O₂ gas, an O₃ gas, an H₂ gas, an N₂ gas, an Ar gas and an He gas for 0.5˜30 seconds.

The purge process is conducted by using a plasma processing power of about 50˜7,000 W for about 0.5˜30 seconds with at least one of an O₂ gas, an H₂ gas, an N₂ gas, an Ar gas, an He gas and an N₂O gas.

The first through fourth steps are repeatedly implemented between about 5 through 150 times.

In another embodiment of the present invention, a method for forming an insulation layer of a semiconductor device comprises a first step of selectively supplying a first source gas into a process chamber in which a semiconductor substrate is placed; a second step of continuously supplying the first source gas supplied in the first step, supplying a second source gas and depositing a silicon oxide layer on the semiconductor substrate; a third step of continuously supplying the first source gas supplied in the second step and interrupting supply of the second source gas; and a fourth step of interrupting supply of the first source gas and conducting a purge process.

The first source gas comprises a silicon source gas and the second source gas comprises an oxygen source gas, or the first source gas comprises an oxygen source gas and the second source gas comprises a silicon source gas.

The silicon source gas comprises at least one of an SiH₄ gas, an Si₂H₆ gas, an Si₃H₈ gas and an Si₄H₈ gas.

The oxygen source gas comprises at least one of an O₂ gas, an O₃ gas, an H₂O gas and an H₂O₂ gas.

The first source gas and the second source gas are supplied at a temperature of about 60˜200° C.

The first source gas supplied in the first step is continuously supplied through the second and third steps for about 2˜30 seconds in total.

The second source gas supplied in the second step is supplied for about 0.5˜20 seconds.

The first through fourth steps are implemented in a state in which the semiconductor substrate is maintained at a temperature of about 10˜200° C.

The second step is implemented for about 0.5˜20 seconds.

The first step is implemented along with a purge process.

The purge process is conducted by supplying at least one of an O₂ gas, an O₃ gas, an H₂ gas, an N₂ gas, an Ar gas and an He gas for about 0.5˜30 seconds.

The purge process is conducted using a plasma processing power of about 50˜7,000 W for about 0.5˜30 seconds supplied with at least one of an O₂ gas, an H₂ gas, an N₂ gas, an Ar gas, an He gas and an N₂O gas.

The first through fourth steps are repeatedly implemented about 5 through 150 times.

In still another aspect of the present invention, a method for forming an insulation layer of a semiconductor device comprises a first step of selectively supplying a first source gas into a process chamber in which a semiconductor substrate is placed; a second step of continuously supplying the first source gas supplied in the first step, supplying a second source gas and depositing a silicon oxide layer on the semiconductor substrate; and a third step of continuously supplying the first source gas supplied in the second step, interrupting supply of the second source gas and conducting a purge process.

The first source gas comprises a silicon source gas and the second source gas comprises an oxygen source gas, or the first source gas comprises an oxygen source gas and the second source gas comprises a silicon source gas.

The silicon source gas comprises at least one of an SiH₄ gas, an Si₂H₆ gas, an Si₃H₈ gas and an Si₄H₈ gas.

The oxygen source gas comprises at least one of an O₂ gas, an O₃ gas, an H₂O gas and an H₂O₂ gas.

The first source gas and the second source gas are supplied at a temperature of about 60˜200° C.

The first through third steps are implemented in a state in which the semiconductor substrate is maintained at a temperature of about 10˜200° C.

The second step is implemented for about 0.5˜20 seconds.

The first step is implemented along with a purge process.

The purge process is conducted by supplying at least one of an O₂ gas, an O₃ gas, an H₂ gas, an N₂ gas, an Ar gas and an He gas for 0.5˜30 seconds.

The purge process is conducted by using a plasma processing power of about 50˜7,000 W for about 0.5˜30 seconds using at least one of an O₂ gas, an H₂ gas, an N₂ gas, an Ar gas, an He gas and an N₂O gas.

After the third step, the second and third steps are repeatedly implemented about 5 through about 150 times.

In a still further aspect of the present invention, a method for forming an insulation layer of a semiconductor device comprises a first step of selectively supplying a first source gas into a process chamber in which a semiconductor substrate is placed; a second step of continuously supplying the first source gas supplied in the first step, supplying a second source gas and depositing a first silicon oxide layer on the semiconductor substrate; a third step of continuously supplying the second source gas supplied in the second step, interrupting supply of the first source gas and conducting a first purge process; a fourth step of continuously supplying the second source gas supplied in the third step, supplying the first source gas and depositing a second silicon oxide layer on the first silicon oxide layer; and a fifth step of continuously supplying the first source gas supplied in the fourth step, interrupting supply of the second source gas and conducting a second purge process.

The first source gas comprises a silicon source gas and the second source gas comprises an oxygen source gas, or the first source gas comprises an oxygen source gas and the second source gas comprises a silicon source gas.

The silicon source gas comprises at least one of an SiH₄ gas, an Si₂H₆ gas, an Si₃H₈ gas and an Si₄H₈ gas.

The oxygen source gas comprises at least one of an O₂ gas, an O₃ gas, an H₂O gas and an H₂O₂ gas.

The first source gas and the second source gas are supplied at a temperature of about 60˜200° C.

The first through fifth steps are implemented in a state in which the semiconductor substrate is maintained at a temperature of about 10˜200° C.

Each of the second step and the forth step is implemented for about 0.5˜20 seconds.

The first step is implemented along with a purge process.

The purge process is conducted by supplying at least one of an O₂ gas, an O₃ gas, an H₂ gas, an N₂ gas, an Ar gas and an He gas for about 0.5-30 seconds.

The purge process is conducted through plasma processing with power of about 50˜7,000 W for about 0.5˜30 seconds using at least one of an O₂ gas, an H₂ gas, an N₂ gas, an Ar gas, an He gas and an N₂O gas.

After the fifth step, the second through fifth steps are repeatedly implemented about 3 through about 75 times.

### BRIEF DESCRIPTION OF THE DRAWINGS

FIG. 1 is a view illustrating a method for forming an insulation layer of a semiconductor device in accordance with a first embodiment of the present invention.

FIG. 2 is a view illustrating a method for forming an insulation layer of a semiconductor device in accordance with a second embodiment of the present invention.

FIG. 3 is a view illustrating a method for forming an insulation layer of a semiconductor device in accordance with a third embodiment of the present invention.

FIG. 4 is a view illustrating a method for forming an insulation layer of a semiconductor device in accordance with a fourth embodiment of the present invention.

### DESCRIPTION OF SPECIFIC EMBODIMENTS

In the present invention, a step of supplying a silicon source gas and an oxygen source gas together and thereby depositing a silicon oxide layer on a semiconductor substrate, and a step of supplying only any one of the source gases before or after depositing the silicon oxide layer are repeatedly implemented. Also, in the present invention, a purge process is repeatedly implemented before or after depositing the silicon oxide layer.

By doing this, as only any one of the source gases is supplied before or after depositing the silicon oxide layer, Si—OH bonds are thought to be produced at the surface, and as a result volumetric shrinkage of an insulation layer can be compensated for. Through this, in the present invention, it is possible to form the insulation layer that exhibits an improved gap-fill characteristics and an improved corresponding quality in performance.

In detail, as the oxygen source gas such as an H₂O or H₂O₂ is gas is supplied before or after depositing the silicon oxide layer, Si—OH bonds are produced, whereby the flow characteristics of the insulation layer can be improved and it is possible to form a flowable insulation layer. Also, as the silicon source gas excluding the H₂O or H₂O₂ gas is supplied before or after depositing the silicon oxide layer, volumetric shrinkage due to discharge of byproducts in the insulation layer can be compensated for. Thereby the quality of the flowable insulation layer can be improved.

Moreover, in the present invention, the insulation is not formed at a single time to achieve the complete thickness, and the step of depositing the silicon oxide layer and the step of supplying only any one of the source gases are repeatedly implemented until the insulation layer having a desired thickness is formed, whereby it is possible to decrease an impurity content of the insulation layer. In particular, in the present invention, due to the fact that the purge process for removing impurities in the insulation layer is repeatedly implemented before or after depositing the silicon oxide layer, the impurity contact can be further decreased. Accordingly, in the present invention, it is possible to form an insulation layer of which the structural integrity and the resulting performance quality is effectively improved.

Hereafter, specific embodiments of the present invention will be described in detail with reference to the accompanying drawings.

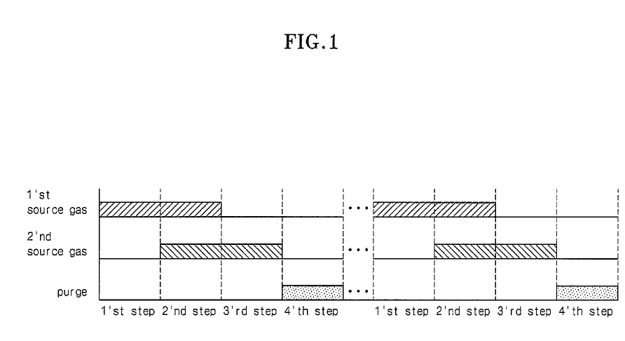

FIG. 1 is a view illustrating a method for forming an insulation layer of a semiconductor device in accordance with a first embodiment of the present invention.

First, a semiconductor substrate is placed on a plate in a process chamber. At this time, in order to prevent byproducts created during the formation of an insulation layer from being confined in the insulation layer, it is preferred that the temperature of the plate in a process chamber be maintained at about 20˜350° C.° C.

Then, a first step of selectively supplying a first source gas into the process chamber in which the semiconductor substrate is placed is implemented. The first source gas comprises any one of a silicon source gas and an oxygen source gas and is supplied at a temperature of about 60˜200° C. The silicon source gas comprises at least one of an SiH₄ gas, an Si₂H₆ gas, an Si₃H₈ gas and an Si₄H₈ gas, and the oxygen source gas comprises at least one of an O₂ gas, an O₃ gas, an H₂O gas and an H₂O₂ gas. The oxygen source gas can comprise a mixed gas of an H₂O gas and an H₂O₂ gas. In this case, the H₂O₂ gas is mixed to form about 50˜140 wt % relative to the H₂O gas.

Next, a second step of continuously supplying the first source gas supplied in the first step, supplying a second source gas and depositing a silicon oxide layer on the semiconductor substrate is implemented. The second source gas comprises a gas which is left by excluding the first source gas from the silicon source gas and the oxygen source gas, and is supplied at a temperature of about 60˜200° C. That is to say, in the case where the first source gas comprises the silicon source gas, the second source gas comprises the oxygen source gas, and in the case where the first source gas comprises the oxygen source gas, the second source gas comprises the silicon source gas. The first source gas and the second source gas are supplied through different nozzles to protect against each reacting with each other along the supply line. The first source gas supplied in the first step is continuously supplied through the second step for about 1˜30 seconds in total. The second step, in which the first source gas and the second source gas are simultaneously supplied and the silicon oxide layer is deposited, is implemented for about 0.5˜20 seconds.

Thereafter, a third step of continuously supplying the second source gas supplied in the second step and interrupting the supply of the first source gas is implemented. The second source gas supplied in the second step is continuously supplied through the third step for about 1˜30 seconds in total.

Thereupon, a fourth step of interrupting the supply of the second source gas and conducting a purge process is implemented. The purge process is conducted by supplying at least one of an O₂ gas, an O₃ gas, an H₂ gas, an N₂ gas, an Ar gas and an He gas for about 0.5˜30 seconds. Also, the purge process can be conducted using a plasma processing power of about 50˜7,000 W for about 0.5˜30 seconds using at least one of an O₂ gas, an H₂ gas, an N₂ gas, an Ar gas, an He gas and an N₂O gas.

In succession, the first through fourth steps are implemented 5 through 150 times until an insulation layer having a desired thickness is formed. The first through fourth steps are implemented at a temperature of, for example, about 80˜200° C., so as to prevent the completely formed insulation layer from condensing under a shower head.

As is apparent from the above description, in the first embodiment of the present invention, a first step and a third step of each supplying only any one source gas of a silicon source gas and an oxygen source gas are implemented before and after a second step of depositing a silicon oxide layer, whereby it is possible to form an insulation layer having improved gap-fill characteristics and improved quality. Also, in the first embodiment of the present invention, by conducting a purge process for removing impurities from a layer after implementing the third step, it is possible to form the insulation layer of which quality is further improved effectively.

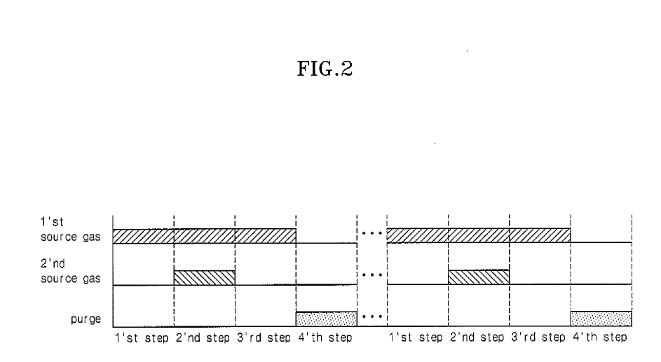

FIG. 2 is a view illustrating a method for forming an insulation layer of a semiconductor device in accordance with a second embodiment of the present invention.

First, a semiconductor substrate is placed on a platen in a process chamber. At this time, in order to prevent byproducts created during the formation of an insulation layer from being confined in the insulation layer, it is preferred that the temperature of the platen be maintained at about 20˜350° C.

Then, a first step of selectively supplying a first source gas into the process chamber in which the semiconductor substrate is placed is implemented. The first source gas comprises any one of a silicon source gas and an oxygen source gas and is supplied at a temperature of about 60˜200° C. The silicon source gas comprises at least one of an SiH₄ gas, an Si₂H₆ gas, an Si₃H₈ gas and an Si₄H₈ gas, and the oxygen source gas comprises at least one of an O₂ gas, an O₃ gas, an H₂O gas and an H₂O₂ gas. The oxygen source gas can comprise a mixed gas of an H₂O gas and an H₂O₂ gas. In this case, the H₂O₂ gas is mixed to about 50˜140 wt % with respect to the H₂O gas in the oxygen source gas.

Next, a second step of continuously supplying the first source gas supplied in the first step, supplying a second source gas and depositing a silicon oxide layer on the semiconductor substrate is implemented. The second source gas comprises a gas which is left by excluding the first source gas from the silicon source gas and the oxygen source gas, and is supplied at a temperature of about 60˜200° C. That is to say, in the case where the first source gas comprises the silicon source gas, the second source gas comprises the oxygen source gas, and in the case where the first source gas comprises the oxygen source gas, the second source gas comprises the silicon source gas. The first source gas and the second source gas are supplied through different nozzles to be prevented from reacting with each other in a supply line. The second source gas is supplied for about 0.5˜20 seconds in the second step. The second step of simultaneously supplying the first source gas and the second source gas and depositing the silicon oxide layer is implemented for about 0.5˜20 seconds.

Thereafter, a third step of continuously supplying the first source gas supplied in the first step and the second step and interrupting the supply of the second source gas is implemented. The first source gas supplied in the first step and the second step is continuously supplied through the third step for about 2˜30 seconds in total.

Thereupon, a fourth step of interrupting the supply of the first source gas supplied in the third step and conducting a purge process is implemented. The purge process is conducted by supplying at least one of an O₂ gas, an O₃ gas, an H₂ gas, an N₂ gas, an Ar gas and an He gas for 0.5˜30 seconds. Also, the purge process can be conducted by using a plasma processing power of about 507,000 W for about 0.5˜30 seconds using at least one of an O₂ gas, an H₂ gas, an N₂ gas, an Ar gas, an He gas and an N₂O gas.

In succession, the first through fourth steps are implemented 5 through 150 times until an insulation layer having a is desired thickness is formed. The first through fourth steps are implemented at a temperature of, for example, about 80˜200° C., so as to prevent the completely formed insulation layer from condensing under a shower head.

As is apparent from the above description, in the second embodiment of the present invention, a first step and a third step of each supplying only any one source gas of a silicon source gas and an oxygen source gas are implemented before and after a second step of depositing a silicon oxide layer, whereby it is possible to form an insulation layer having improved gap-fill characteristics and improved quality. Also, in the second embodiment of the present invention, by conducting a purge process for removing impurities from a layer after implementing the third step, it is possible to form the insulation layer of which quality is further improved effectively.

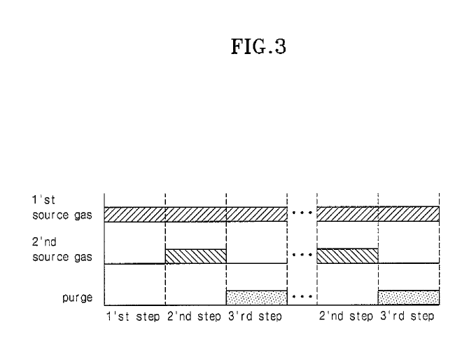

FIG. 3 is a view illustrating a method for forming an insulation layer of a semiconductor device in accordance with a third embodiment of the present invention.

First, a semiconductor substrate is placed on a platen in a process chamber. At this time, in order to prevent byproducts created during the formation of an insulation layer from being confined in the insulation layer, it is preferred that the temperature of the platen be maintained at about 20˜350° C.

Then, a first step of selectively supplying a first source gas into the process chamber in which the semiconductor substrate is placed is implemented. The first source gas comprises any one of a silicon source gas and an oxygen source gas and is supplied at a temperature of 60˜200° C. The silicon source gas comprises at least one of an SiH₄ gas, an Si₂H₆ gas, an Si₃H₈ gas and an Si₄H₈ gas, and the oxygen source gas comprises at least one of an O₂ gas, an O₃ gas, an H₂O gas and an H₂O₂ gas. The oxygen source gas can comprise a mixed gas of an H₂O gas and an H₂O₂ gas. In this case, the H₂O₂ gas is mixed to form about 50˜140 wt % relative to the H₂O gas.

Next, a second step of continuously supplying the first source gas supplied in the first step, supplying a second source gas and depositing a silicon oxide layer on the semiconductor substrate is implemented. The second source gas comprises a gas which is left by excluding the first source gas from the silicon source gas and the oxygen source gas, and is supplied at a temperature of about 60˜200° C. That is to say, in the case where the first source gas comprises the silicon source gas, the second source gas comprises the oxygen source gas, and in the case where the first source gas comprises the oxygen source gas, the second source gas comprises the silicon source gas. The first source gas and the second source gas are supplied through different nozzles to be prevented from reacting with each other in a supply line. The second source gas is supplied for about 0.5˜20 seconds in the second step. The second step of simultaneously supplying the first source gas and the second source gas and depositing the silicon oxide layer is implemented for about 0.5˜20 seconds.

Thereafter, a third step of continuously supplying the first source gas supplied in the first step and the second step, interrupting the supply of the second source gas and conducting a purge process is implemented. The first source gas supplied in the first step and the second step is continuously supplied through the third step. The purge process is conducted by supplying at least one of an O₂ gas, an O₃ gas, an H₂ gas, an N₂ gas, an Ar gas and an He gas for about 0.5˜30 seconds. Also, the purge process can be conducted by using a plasma process with power of about 50˜7,000 W for about 0.5˜30 seconds with least one of an O₂ gas, an H₂ gas, an N₂ gas, an Ar gas, an He gas and an N₂O gas.

In succession, after the third step, the second and third steps are implemented 5 through 150 times until an insulation layer having a desired thickness is formed. In other words, in the third embodiment of the present invention, the first source gas is continuously supplied, and the supply of the second source gas and the purge process are alternately conducted. The first through third steps are implemented at a temperature of, for example, about 80˜200° C., so as to prevent the completely formed insulation layer from condensing under a shower head.

As is apparent from the above description, in the third embodiment of the present invention, a first step and a third step of each supplying only any one source gas of a silicon source gas and an oxygen source gas are implemented before and after a second step of depositing a silicon oxide layer, whereby it is possible to form an insulation layer having improved gap-fill characteristics and improved quality. Also, in the third embodiment of the present invention, by supplying only any one source gas and simultaneously conducting a purge process for removing impurities from a layer in the third step, it is possible to form the insulation layer of which quality is further improved effectively.

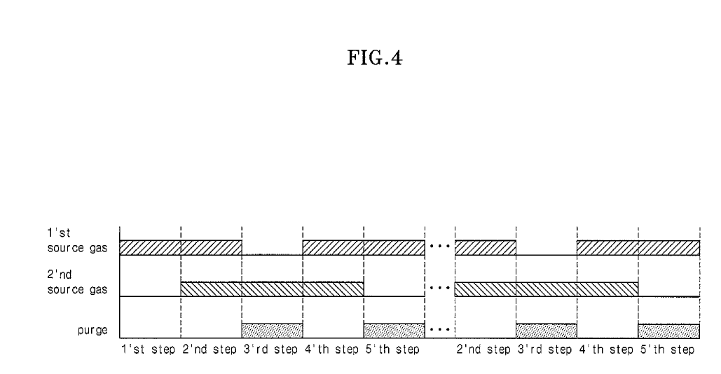

FIG. 4 is a view illustrating a method for forming an insulation layer of a semiconductor device in accordance with a fourth embodiment of the present invention.

First, a semiconductor substrate is placed on a plate in a process chamber. At this time, in order to prevent byproducts created during the formation of an insulation layer from being confined in the insulation layer, it is preferred that the temperature of the platen be maintained at about 20˜350° C.

Then, a first step of selectively supplying a first source gas into the process chamber in which the semiconductor substrate is placed is implemented. The first source gas comprises any one of a silicon source gas and an oxygen source gas and is supplied at a temperature of about 60˜200° C. The silicon source gas comprises at least one of an SiH₄ gas, an Si₂H₆ gas, an Si₃H₈ gas and an Si₄H₈ gas, and the oxygen source gas comprises at least one of an O₂ gas, an O₃ gas, an H₂O gas and an H₂O₂ gas. The oxygen source gas can comprise a mixed gas of an H₂O gas and an H₂O₂ gas. In this case, the H₂O₂ gas is mixed to about 50˜140 wt % relative to the H₂O gas.

Next, a second step of continuously supplying the first source gas supplied in the first step, supplying a second source gas and depositing a first silicon oxide layer on the semiconductor substrate is implemented. The second source gas comprises a gas which is left by excluding the first source gas from the silicon source gas and the oxygen source gas, and is supplied at a temperature of about 60˜200° C. That is to say, in the case where the first source gas comprises the silicon source gas, the second source gas comprises the oxygen source gas, and in the case where the first source gas comprises the oxygen source gas, the second source gas comprises the silicon source gas. The first source gas and the second source gas are supplied through different nozzles to be prevented from reacting with each other in a supply line. The second step of simultaneously supplying the first source gas and the second source gas and depositing the silicon oxide layer is implemented for about 0.5˜20 seconds.

Thereafter, a third step of continuously supplying the second source gas supplied in the second step, interrupting the supply of the first source gas and conducting a first purge process is implemented. The first purge process is conducted by supplying at least one of an O₂ gas, an O₃ gas, an H₂ gas, an N₂ gas, an Ar gas and an He gas for about 0.5˜30 seconds. Also, the first purge process can be conducted by using a plasma process with a power of about 50˜7,000 W for about 0.5˜30 seconds supplied with at least one of an O₂ gas, an H₂ gas, an N₂ gas, an Ar gas, an He gas and an N₂O gas.

Then, a fourth step of continuously supplying the second source gas supplied in the third step, supplying the first source gas and depositing a second silicon oxide layer on the first silicon oxide layer is implemented. The first source gas and the second source gas are supplied at a temperature of about 60˜200° C. The fourth step of simultaneously supplying the first source gas and the second source gas and depositing the second silicon oxide layer is implemented for about 0.5˜20 seconds.

Next, a fifth step of continuously supplying the first source gas supplied in the fourth step, interrupting the supply of the second source gas and conducting a second purge process is implemented. The second purge process is conducted by supplying at least one of an O₂ gas, an O₃ gas, an H₂ gas, an N₂ gas, an Ar gas and an He gas for about 0.5˜30 seconds. Also, the second purge process can be conducted by using a plasma process with a power of about 50˜7,000 W for about 0.5˜30 seconds supplied with at least one of an O₂ gas, an H₂ gas, an N₂ gas, an Ar gas, an He gas and an N₂O gas. Meanwhile, the second purge process may be conducted using a gas different from that of the first purge process.

In succession, after the fifth step, the second through fifth steps are implemented about 3 through about 75 times until an insulation layer having a desired thickness is formed. The first through fifth steps are implemented at a temperature of, for example, about 80˜200° C., so as to prevent the completely formed insulation layer from condensing under a shower head.

As is apparent from the above description, in the fourth embodiment of the present invention, a first step, a third step and a fifth step of each supplying only any one source gas of a silicon source gas and an oxygen source gas are implemented before and after a second step and a fourth step of depositing silicon oxide layers, whereby it is possible to form an insulation layer having improved gap-fill characteristics and improved quality. Also, in the fourth embodiment of the present invention, by supplying only any one source gas and simultaneously conducting purge processes for removing impurities from a layer in the third step and the fifth step, it is possible to form the insulation layer of which quality is further improved effectively.

Although specific embodiments of the present invention have been described for illustrative purposes, those skilled in the art will appreciate that various modifications, additions and substitutions are possible, without departing from the scope and the is spirit of the invention as disclosed in the accompanying claims.

What is claimed is:

1. A method for forming an insulation layer of a semiconductor device, comprising:
a first step of supplying any one of a silicon source gas and an oxygen source gas into a process chamber in which a semiconductor substrate is placed;
a second step of simultaneously supplying the silicon source gas and the oxygen source gas into the process chamber having undergone the first step and depositing a silicon oxide layer on the semiconductor substrate; and
a third step of supplying any one of the silicon source gas and the oxygen source gas into the process chamber having undergone the second step.

2. The method according to claim 1, wherein the silicon source gas and the oxygen source gas are supplied at a temperature of about 60˜200° C.

3. The method according to claim 1, wherein the first through third steps are implemented in a state in which the semiconductor substrate is maintained at a temperature of about 10˜200° C.

4. The method according to claim 1, wherein, after the first through third steps are implemented, the method further comprises:
a fourth step of interrupting supply of a source gas supplied in the third step and conducting a purge process.

5. The method according to claim 4, wherein the first through fourth steps are repeatedly implemented about 5 through about 150 times.

6. The method according to claim 1, wherein the first step or the third step is implemented along with a purge process.

7. The method according to claim 6, wherein the first through third steps are repeatedly implemented about 5 through about 150 times.

8. The method according to any one of claims 4 and 6, wherein the purge process is conducted by supplying at least one of an O₂ gas, an O₃ gas, an H₂ gas, an N₂ gas, an Ar gas and an He gas for about 0.5˜30 seconds or through plasma processing with power of about 50˜7,000 W for about 0.5˜30 seconds using at least one of an O₂ gas, an H₂ gas, an N₂ gas, an Ar gas, an He gas and an N₂O gas.

9. A method for forming an insulation layer of a semiconductor device, comprising:
a first step of selectively supplying a first source gas into a process chamber in which a semiconductor substrate is placed;
a second step of continuously supplying the first source gas supplied in the first step, supplying a second source gas and depositing a silicon oxide layer on the semiconductor substrate;
a third step of continuously supplying the second source gas supplied in the second step and interrupting supply of the first source gas; and
a fourth step of interrupting supply of the second source gas and conducting a purge process.

10. The method according to claim 9, wherein the first source gas comprises a silicon source gas and the second source gas comprises an oxygen source gas, or the first source gas comprises an oxygen source gas and the second source gas comprises a silicon source gas.

11. The method according to claim 9, wherein the first through fourth steps are repeatedly implemented about 5 through about 150 times.

12. A method for forming an insulation layer of a semiconductor device, comprising:
a first step of selectively supplying a first source gas into a process chamber in which a semiconductor substrate is placed;
a second step of continuously supplying the first source gas supplied in the first step, supplying a second source gas and depositing a silicon oxide layer on the semiconductor substrate;
a third step of continuously supplying the first source gas supplied in the second step and interrupting supply of the second source gas; and
a fourth step of interrupting supply of the first source gas and conducting a purge process.

13. The method according to claim 12, wherein the first source gas comprises a silicon source gas and the second source gas comprises an oxygen source gas, or the first source gas comprises an oxygen source gas and the second source gas comprises a silicon source gas.

14. The method according to claim 12, wherein the first through fourth steps are repeatedly implemented about 5 through about 150 times.

15. A method for forming an insulation layer of a semiconductor device, comprising:
a first step of selectively supplying a first source gas into a process chamber in which a semiconductor substrate is placed;
a second step of continuously supplying the first source gas supplied in the first step, supplying a second source gas and depositing a silicon oxide layer on the semiconductor substrate; and
a third step of continuously supplying the first source gas supplied in the second step, interrupting supply of the second source gas and conducting a purge process.

16. The method according to claim 15, wherein the first source gas comprises a silicon source gas and the second source gas comprises an oxygen source gas, or the first source gas comprises an oxygen source gas and the second source gas comprises a silicon source gas.

17. The method according to claim 15, wherein, after the third step, the second and third steps are repeatedly implemented about 5 through about 150 times.

18. A method for forming an insulation layer of a semiconductor device, comprising:
a first step of selectively supplying a first source gas into a process chamber in which a semiconductor substrate is placed;
a second step of continuously supplying the first source gas supplied in the first step, supplying a second source gas and depositing a first silicon oxide layer on the semiconductor substrate;
a third step of continuously supplying the second source gas supplied in the second step, interrupting supply of the first source gas and conducting a first purge process;
a fourth step of continuously supplying the second source gas supplied in the third step, supplying the first source gas and depositing a second silicon oxide layer on the first silicon oxide layer; and
a fifth step of continuously supplying the first source gas supplied in the fourth step, interrupting supply of the second source gas and conducting a second purge process.

19. The method according to claim 18, wherein the first source gas comprises a silicon source gas and the second source gas comprises an oxygen source gas, or the first source gas comprises an oxygen source gas and the second source gas comprises a silicon source gas.

20. The method according to claim 18, wherein, after the fifth step, the second through fifth steps are repeatedly implemented about 3 through about 75 times.
